(19) United States
(12) Patent Application Publication
(10) Pub. No.: US 2026/0068503 A1
(43) Pub. Date: Mar. 5, 2026

(54) DISPLAY DEVICE

(71) Applicant: Samsung Display Co., LTD., Yongin-si (KR)

(72) Inventors: Eun Hye KIM, Yongin-si (KR); Dong Hyun SON, Yongin-si (KR); KIYOUNG KIM, Yongin-si (KR); DONGHUN NAM, Yongin-si (KR); Jiyun Park, Yongin-si (KR); SOLA LEE, Yongin-si (KR)

(73) Assignee: Samsung Display Co., LTD., Yongin-si (KR)

(21) Appl. No.: 19/198,534

(22) Filed: May 5, 2025

(30) Foreign Application Priority Data
Sep. 3, 2024 (KR) 10-2024-0119270

(51) Int. Cl. H10K 59/80; H10K 59/40

(52) U.S. Cl. CPC H10K 59/879; H10K 59/40

(57) ABSTRACT

A display device includes: a display panel including a first area and a second area; and a sensing module overlapping the first area of the display panel, wherein the first area of the display panel includes: a plurality of pixels; a diffusion pattern disposed between the plurality of pixels; and a planarization layer disposed in the diffusion pattern, and a refractive index of the diffusion pattern and a refractive index of the planarization layer are different from each other.

### CROSS-REFERENCE TO RELATED APPLICATION(S)

This application claims priority to and benefits of Korean Patent Application No. 10-2024-0119270 under 35 U.S. C. § 119, filed on Sep. 3, 2024, in the Korean Intellectual Property Office, the entire contents of which are incorporated herein by reference.

### BACKGROUND

### 1. Technical Field

Embodiments relate to a display device.

### 2. Description of the Related Art

A display device may display an image using a pixel (or a pixel circuit). The display device includes an infrared sensor on a bezel (or a border) of the front of the display device (e.g., a side where the image is displayed), and may recognize an object using the infrared sensor. For example, the display device may transmit infrared light using the infrared sensor, receive the reflected light reflected by the object, calculate a distance between the display device and the object based on the intensity of the reflected light, and may not display an image in case that the distance is within a certain distance.

Meanwhile, as the bezel of the display device becomes thinner, the user's gaze can be fixed or focused on the image (or the screen of the display device). Recently, research and development are being conducted on the front display technology that eliminates the bezel on the front of the display device, relocates the infrared sensor that is located on the front (or bezel), and displays an image on the entire front of the display device.

### SUMMARY

Embodiments provide a display device with improved performance of a sensing module.

However, embodiments are not limited to those set forth herein. The above and other embodiments will become more apparent to one of ordinary skill in the art to which the disclosure pertains by referencing the detailed description of the disclosure given below.

A display device according to an embodiment includes: a display panel including a first area and a second area; and a sensing module overlapping the first area of the display panel, wherein the first area of the display panel includes: a plurality of pixels; a diffusion pattern disposed between the plurality of pixels; and a planarization layer disposed on the diffusion pattern, and a refractive index of the diffusion pattern and a refractive index of the planarization layer are different from each other.

The refractive index of the diffusion pattern may be smaller than the refractive index of the planarization layer.

The refractive index of the diffusion pattern may be greater than the refractive index of the planarization layer.

The diffusion pattern may not overlap the plurality of pixels.

The diffusion pattern may not be disposed in the second area.

A planar area of the diffusion pattern is smaller than a planar area of each of the plurality of pixels.

A number of diffusion patterns may be greater than a number of pixels in a unit area of the first area.

A planar shape of the diffusion pattern may be dot-shaped.

A planar shape of the diffusion pattern may be bar-shaped.

A planar shape of the diffusion pattern may be wave-shaped.

A cross-section of the diffusion pattern may have a circular shape.

A radius of a bottom surface of the diffusion pattern and a height of the diffusion pattern may be substantially equal to each other.

A height of the diffusion pattern may be greater than a radius of a bottom surface of the diffusion pattern.

A radius of a bottom surface of the diffusion pattern may be greater than a height of the diffusion pattern.

A light emitted from the sensing module may be diffused at an interface of the diffusion pattern and the planarization layer.

The sensing module may be an infrared sensing module.

A display device according to another embodiment includes: a display panel including a first area and a second area; and a sensing module overlapping the first area of the display panel, wherein the first area of the display panel includes: a pixel area where a plurality of pixels are disposed; and a refraction area where a plurality of diffusion patterns and a planarization layer are disposed, the plurality of pixels are not disposed in the refraction area, and a refractive index of the diffusion pattern and a refractive index of the planarization layer are different from each other.

A planar shape of the at least one of the plurality of diffusion patterns may be one of a dot shape, a bar shape, or a wave shape.

A cross-section of the at least one of the plurality of diffusion patterns may have a circular shape.

A light emitted from the sensing module may be diffused at an interface of the at least one of the plurality of diffusion patterns and the planarization layer.

According to the embodiments, the display device with improved performance of the sensing module is provided.

### BRIEF DESCRIPTION OF THE DRAWINGS

FIG. 1 and FIG. 2 are schematic views of a display device according to an embodiment.

FIG. 3 is a schematic plan view of the pixel arrangement of a second area.

FIG. 4 is a schematic cross-sectional view of FIG. 3, taken along the line IV-IV′.

FIG. 5 is a schematic plan view of the pixel arrangement in a first area.

FIG. 6 is a schematic cross-sectional view of FIG. 5, taken along the line V-VI′.

FIG. 7 illustrates a diffusion path of light with respect to the schematic cross-section as FIG. 6.

FIG. 8 illustrates the schematic cross-section as FIG. 6 for another embodiment.

FIG. 9 shows a diffusion simulation result for a diffusion pattern having the shape of FIG. 8.

FIG. 10 illustrates the schematic cross-section as FIG. 6 for another embodiment.

FIG. 11 shows a diffusion simulation result for a diffusion pattern having the shape of FIG. 10.

FIG. 12 illustrates the schematic cross-section as FIG. 6 for another embodiment.

FIG. 13 shows a diffusion simulation result for a diffusion pattern having the shape of FIG. 12.

FIG. 14 illustrates the schematic cross-section as FIG. 6 for another embodiment.

FIG. 15 shows a diffusion simulation result for a diffusion pattern having the shape of FIG. 14.

FIG. 16 illustrates a diffusion simulation result in a display device including a diffusion pattern having a shape similar to that of FIG. 8, in which a refractive index of a diffusion pattern is higher than a refractive index of a planarization layer.

FIG. 17 illustrates a diffusion simulation result in a display device including a diffusion pattern having a shape similar to that of FIG. 10, in which a refractive index of a diffusion pattern is higher than a refractive index of a planarization layer.

FIG. 18 illustrates the same region as FIG. 5 for another embodiment.

FIG. 19 illustrates the same region as FIG. 5 for another embodiment.

FIG. 20 illustrates the same region as FIG. 5 for another embodiment.

FIG. 21 illustrates the same region as FIG. 18 for another embodiment.

FIG. 22 illustrates the same region as FIG. 19 for another embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction D1, the axis of the second direction D2, and the axis of the third direction D3 are not limited to three axes of a rectangular coordinate system, such as the X, Y, and Z—axes, and may be interpreted in a broader sense. For example, the axis of the first direction D1, the axis of the second direction D2, and the axis of the third direction D3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

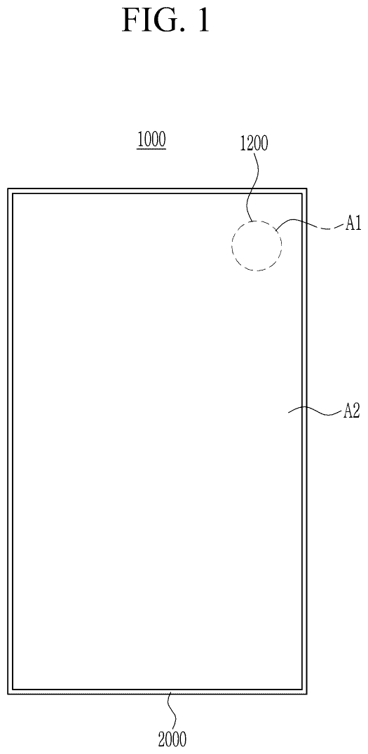

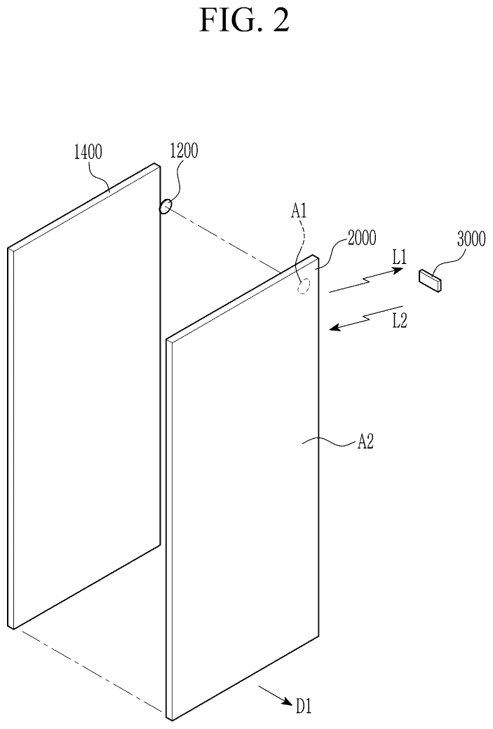

Hereinafter, a display device according to an embodiment will be described with reference to the accompanying drawings. FIG. 1 and FIG. 2 are schematic views of a display device according to an embodiment.

Referring to FIG. 1, a display device 1000 according to an embodiment may include a display panel 2000 and a sensing module 1200.

The display panel 2000 may be an organic light emitting panel including an organic light emitting element. The display panel 2000 may include a first area A1 overlapping a sensing module 1200 and a second area A2 not overlapping the sensing module 1200.

The display panel 2000 may display an image and may display the image on the entire front surface of the display panel 2000 (e.g., a surface in a first direction D1 of the display panel 2000 as shown in FIG. 2). For example, the display panel 2000 may not include a bezel or non-display area on the front.

The sensing module 1200 may be disposed on a rear surface of the display panel 2000, e.g., on a surface in the opposite direction of the first direction D1 of the display panel 2000. For example, the sensing module 1200 may be disposed between the display panel 2000 and a case 1400 (or a cover). For example, the case 1400 forms an outer shape of the display device 1000 and may protect internal components such as a battery and a memory device from external stress.

The sensing module 1200 may be an infrared sensing module. However, embodiments are not limited thereto.

Referring to FIG. 2, in case that the sensing module 1200 is an infrared sensing module, the sensing module 1200 may transmit a first infrared light L1, receive a second infrared light L2, and may recognize an object 3000 based on the change in the second infrared light L2. For example, the first infrared light L1 may travel (or transmit) in the first direction D1 and may penetrate the first area A1 of the display panel 2000. The second infrared light L2 may include a reflected light of the first infrared light L1 reflected by the object 3000, may travel (or transmit) in the opposite direction to the first direction D1, and may penetrate the first area A1 of the display panel 2000.

Pixels may be disposed in both first area A1 and second area A2. For example, since a separate opening for light transmission is not disposed in the first area A1 that overlaps the sensing module 1200, the infrared light of the sensing module 1200 may be required to penetrate through the display panel 2000 for the effective operation of the sensing module 1200. The display device according to an embodiment may be characterized by effectively diffusing and transmitting light of the sensing module 1200 by placing a diffusion pattern 520 in a region where pixels are not positioned in the first area A1. The specific structure will be described with reference to the drawing below.

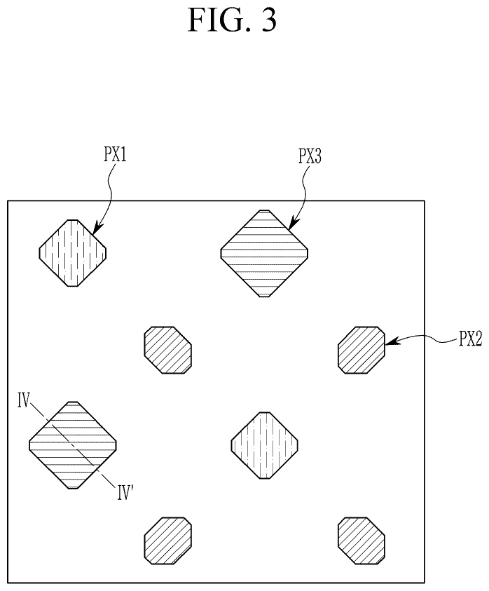

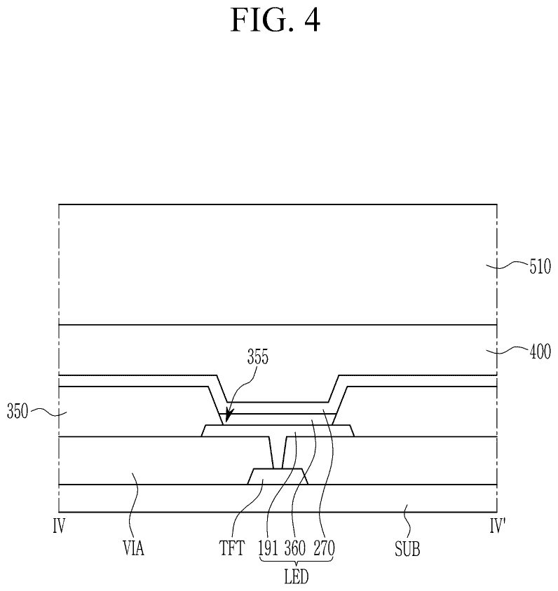

FIG. 3 is a schematic plan view of the pixel arrangement of the second area A2. FIG. 4 is a cross-sectional view of FIG. 3, taken along the line IV-IV′. Referring to FIG. 3, a first pixel PX1, a second pixel PX2, and a third pixel PX3 may be disposed in the second area A2. Referring to FIG. 4, the display device according to an embodiment may include a substrate SUB and a transistor TFT disposed on the substrate SUB. An insulation layer VIA may be disposed on the transistor TFT, and a first electrode 191 may be disposed on the insulation layer VIA. A partitioning wall 350 may be disposed on the first electrode 191, and the partitioning wall 350 may include an opening 355 overlapping the first electrode 191. A light-emitting layer 360 may be disposed in the opening 355. A second electrode 270 may be disposed on the partitioning wall 350 and the light-emitting layer 360. The first electrode 191, the light-emitting layer 360, and the second electrode 270 may form a light-emitting element LED. A portion where the first electrode 191, the light-emitting layer 360, and the second electrode 270 overlap may be a light emitting area where substantially light emitting occurs.

An encapsulation layer 400 may be disposed on the light-emitting element LED. The encapsulation layer 400 may contact (or be in contact with) the second electrode 270, or may be spaced apart from the second electrode 270 according to the embodiment. The encapsulation layer 400 may be a thin film encapsulation layer in which an inorganic film and an organic film are laminated, and may include a triple layer formed of an inorganic film, an organic film, and an inorganic film. According to embodiments, a capping layer and a function layer may be disposed between the second electrode 270 and the encapsulation layer 400.

A planarization layer 510 may be disposed on the encapsulation layer 400. For example, the planarization layer may be a high-refractive index layer. For example, the refractive index of planarization layer 510 may be greater than about 1.6, and for example, greater than about 1.8. The planarization layer 510 may include a ceramic material such as TiO₂, ZrO₂, ZnO, or a polymer material including such a ceramic material, and may be formed through a solution process, chemical vapor deposition (CVD), sputtering, and the like. The planarization layer 510 may include inorganic materials such as SiOₓN_{y}, SiNₓ, AlOₓ, and ZnS, and may be formed through thermal deposition, CVD, and sputtering. In another example, the planarization layer 510 may include a single molecule organic material, which is formed through thermal deposition, a solution process, and the like. In another example, the planarization layer 510 may include a high refractive index polymer material such as polyethylene naphthalate (PEN) or polyimide (PI), which is formed through a solution process, CVD, and the like. The planarization layer 510 may include a composite material including one or more of the materials described above.

In another embodiment, the planarization layer 510 may be a low-refractive index layer. The refractive index of the planarization layer 510 may be less than about 1.5. The planarization layer 510 may include a polymer material such as an acryl-based resin, a methacryl-based resin, a polyisoprene, a vinyl-based resin, an epoxy-based resin, a urethane-based resin, a cellulose-based resin, a siloxane-based resin, a polyimide-based resin, a polyamide-based resin, and a perylene-based resin, and the planarization layer 510 may be formed through a thermal deposition or a solution process. In another example, the planarization layer 510 may include an inorganic material such as SiO₂, MgF₂, LiF, and the like, and may be formed through a thermal deposition, CVD, sputtering, and the like. The planarization layer 510 may include a composite material including one or more of the materials described above.

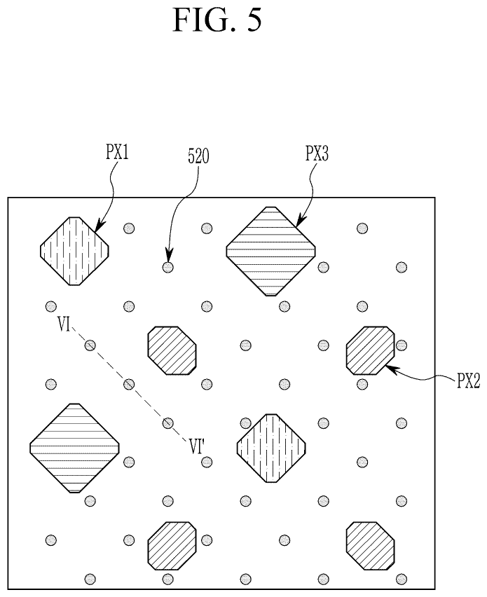

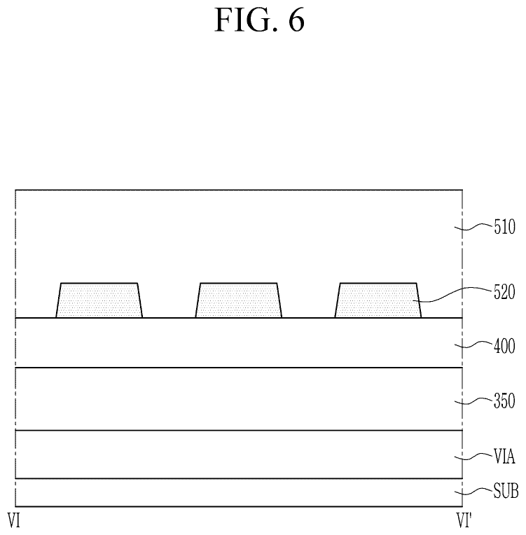

FIG. 5 is a schematic plan view of the pixel arrangement in the first area A1. FIG. 6 is a cross-sectional view of FIG. 5, taken along the line V-VI′. Referring to FIG. 5, the first pixel PX1, the second pixel PX2, and the third pixel PX3 may be disposed in the first area A1. For example, a diffusion pattern 520 may be disposed between the first pixel PX1, the second pixel PX2, and the third pixel PX3. Referring to FIG. 6, the display device according to an embodiment may include a substrate SUB and an encapsulation layer 400 disposed on the substrate SUB. The cross-section of FIG. 6 is a cross-section of a part where pixels are not disposed, and the light-emitting element LED is not shown. However, the cross-section of a part where pixels PX1, PX2, and PX3 are disposed in FIG. 5 may be the same as that in FIG. 4. The encapsulation layer 400 may be a thin film encapsulation layer in which an inorganic film and an organic film are laminated, and may include a triple layer formed of an inorganic film, an organic film, and an inorganic film.

The diffusion pattern 520 may be disposed on the encapsulation layer 400. The planarization layer 510 may be disposed on the diffusion pattern 520. A refractive index of diffusion pattern 520 may be different from the refractive index of the planarization layer 510. In case that the planarization layer 510 has a high refractive index, the diffusion pattern 520 may have a low refractive index. In case that the refractive index of planarization layer 510 is greater than or equal to about 1.6, the refractive index of diffusion pattern 520 may be less than or equal to about 1.5. For example, the diffusion pattern 520 may include a polymer material such as an acryl-based resin, a methacryl-based resin, a polyisoprene, a vinyl-based resin, an epoxy-based resin, a urethane-based resin, a cellulose-based resin, a siloxane-based resin, a polyimide-based resin, a polyamide-based resin, and a perylene-based resin, and the diffusion pattern 520 may be formed through a thermal deposition or a solution process. In another example, the diffusion pattern 520 may include an inorganic material such as SiO₂, MgF₂, LiF, and the like, and may be formed through a thermal deposition, CVD, sputtering, and the like. The planarization layer 510 may include a composite material including one or more of the materials described above.

In case that the refractive index of planarization layer 510 is less than or equal to about 1.5, the refractive index of diffusion pattern 520 may be greater than or equal to about 1.6. For example, the diffusion pattern 520 may include a ceramic material such as TiO₂, ZrO₂, ZnO, or a polymer material including such a ceramic material, and may be formed through a solution process, CVD, sputtering, and the like. The diffusion pattern 520 may include inorganic materials such as SiOₓN_{y}, SiNₓ, AlOₓ, and ZnS, and may be formed through thermal deposition, CVD, and sputtering. In another example, the diffusion pattern 520 may include a single molecule organic material, which is formed through thermal deposition, a solution process, and the like. In another example, the diffusion pattern 520 may include a high refractive index polymer material such as polyethylene naphthalate (PEN) or polyimide (PI), which is formed through a solution process, CVD, and the like. The diffusion pattern 520 may include a composite material including one or more of the materials described above.

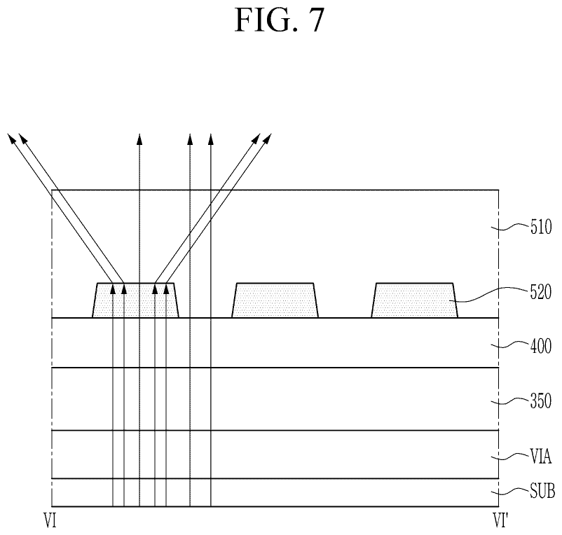

Referring to FIG. 5 and FIG. 6, the diffusion pattern 520 may be disposed in an area where the pixel PX1, the PX2, and the PX3 are not disposed. The diffusion pattern 520 may diffuse the light from the sensing module 1200 below due to a difference in refractive index with the planarization layer 510. FIG. 7 illustrates a diffusion path of the light with respect to the schematic cross-section as FIG. 6. As shown in FIG. 7, light (for example, infrared) emitted from the sensing module may be diffused as it passes through the diffusion pattern 520. Therefore, the detection performance and efficiency of the sensing module may be improved.

Referring to FIG. 5, the planar area (or planar size) of each diffusion pattern 520 may be smaller than the planar area (or planar size) of the smallest pixel among the pixels PX1, PX2, and PX3. There may be a problem of decreased diffusion efficiency in case that the planar area of the diffusion pattern 520 is greater than the planar area of the smallest pixel among the pixels PX1, PX2, and PX3. For example, the total number of diffusion patterns 520 in a given repetition unit, e.g., unit area, may be greater than the total number of the pixels PX1, PX2, and PX3. This is a range for effective diffusion by the diffusion pattern 520.

In FIG. 6 to FIG. 7, the shape of the diffusion pattern 520 is illustrated as a quadrangle in cross-section, but this is an example and the shape of the cross-section of the diffusion pattern 520 may vary.

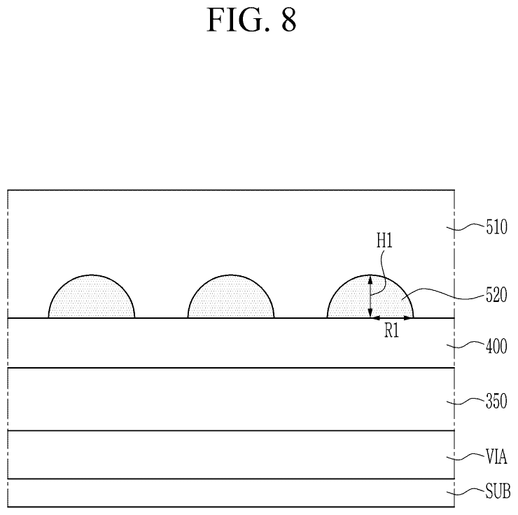

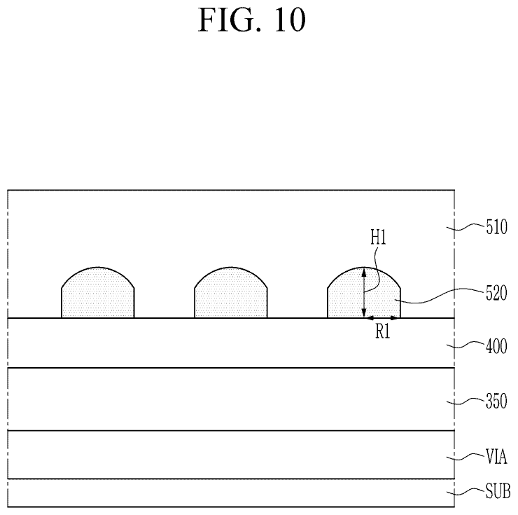

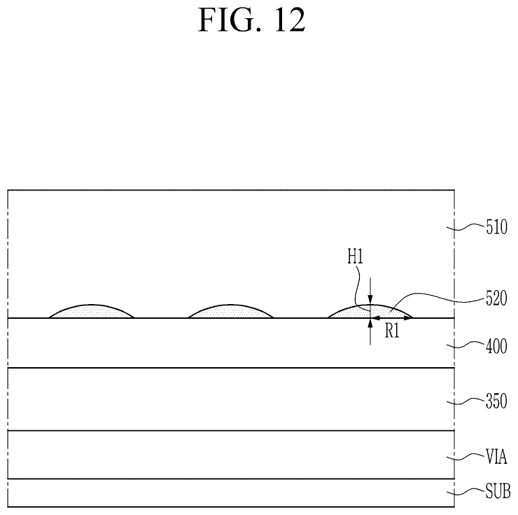

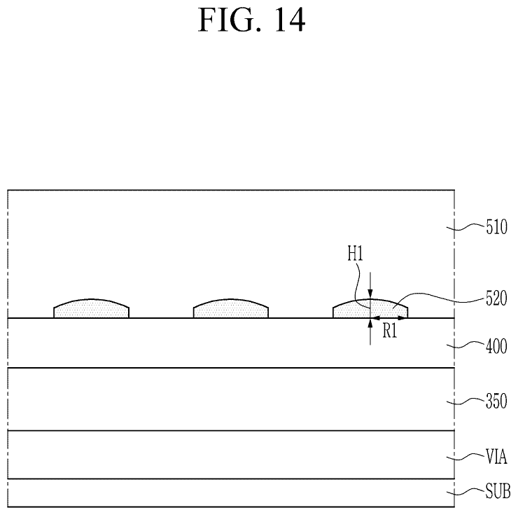

For example, the cross-section of the diffusion pattern 520 may be circular. FIG. 8, FIG. 10, FIG. 12 and FIG. 14 illustrate the schematic cross-section as FIG. 6 for another embodiment. FIG. 8, FIG. 10, FIG. 12, and FIG. 14 are identical or similar to FIG. 6 except for the shape of the diffusion pattern 520. Descriptions of the same components are omitted for descriptive convenience.

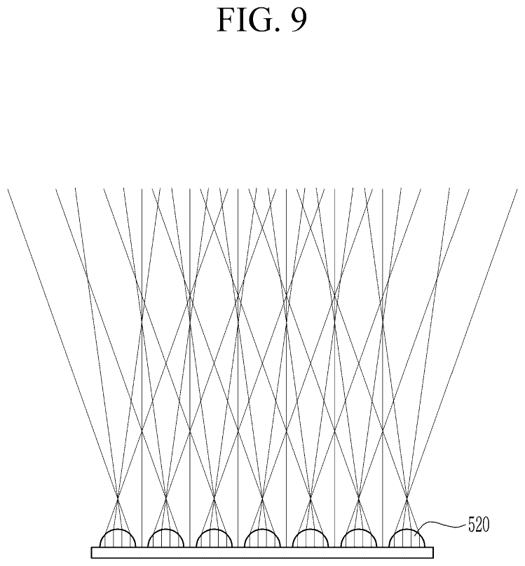

As shown in FIG. 8, the cross-sectional shape of the diffusion pattern 520 may be circular. For example, a radius R1 of a bottom surface of the diffusion pattern 520 and a height H1 of the diffusion pattern 520 may be the same. In case that the cross-section shape of the diffusion pattern 520 is circular, the light may be diffused better. FIG. 9 shows the diffusion simulation result for the diffusion pattern 520 having the shape of FIG. 8. Referring to FIG. 9, it is confirmed that diffusion occurs evenly.

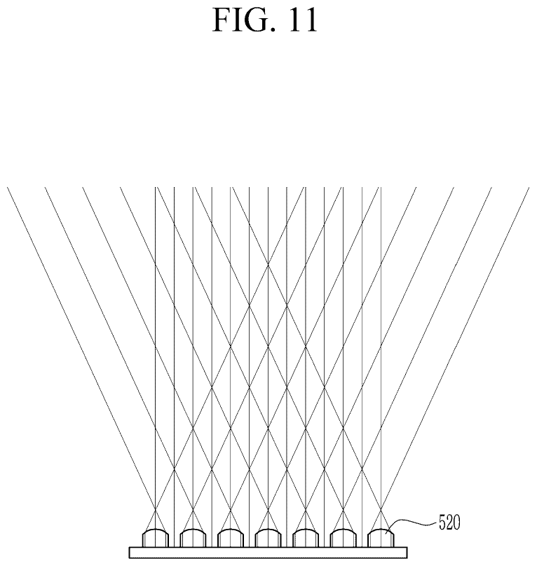

FIG. 10 illustrates the schematic cross-section as FIG. 8 with respect to another embodiment. Referring to FIG. 10, in a display device according to an embodiment, a height H1 of a diffusion pattern 520 may be greater than a radius R1 of a bottom surface of the diffusion pattern 520. FIG. 11 shows a diffusion simulation result for the diffusion pattern 520 having the shape of FIG. 10. Referring to FIG. 11, it may be confirmed that diffusion occurs evenly.

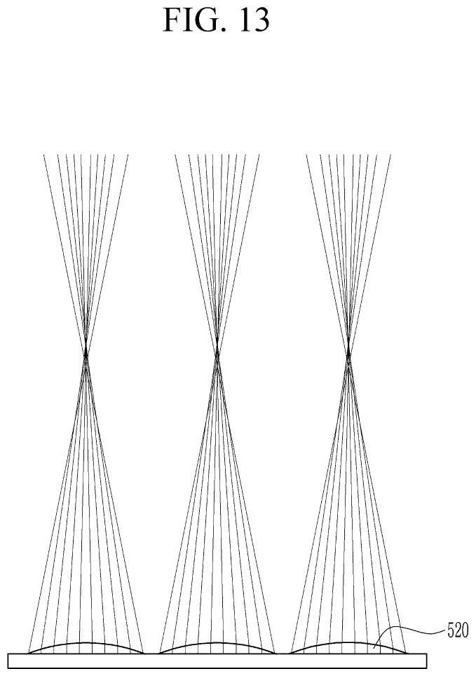

FIG. 12 illustrates the schematic cross-section as FIG. 8 with respect to another embodiment. Referring to FIG. 12, a diffusion pattern 520 according to an embodiment may have a radius R1 of a bottom surface greater than a height H1 of the diffusion pattern 520. FIG. 13 shows a diffusion simulation result for the diffusion pattern 520 having the shape of FIG. 12. Referring to FIG. 13, it may be confirmed that diffusion occurs evenly. However, compared to the embodiments of FIG. 8 and FIG. 10, it may be confirmed that diffusion occurs in a narrow range.

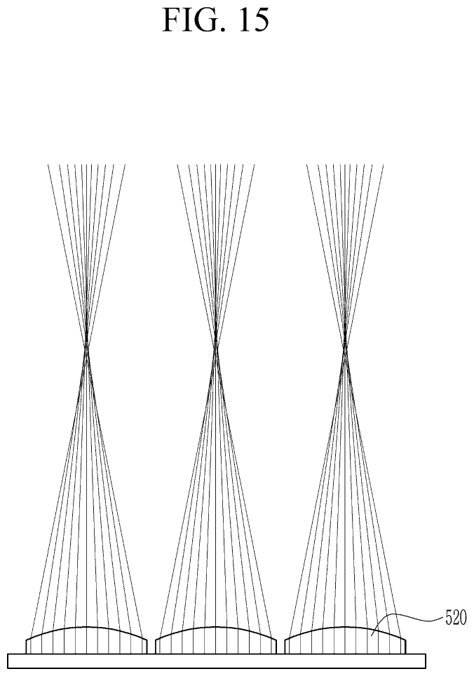

FIG. 14 illustrates the schematic cross-section as FIG. 8 with respect to another embodiment. Referring to FIG. 14, a diffusion pattern 520 according to an embodiment may have a radius R1 of a bottom surface greater than a height H1 of the diffusion pattern 520. FIG. 15 shows a diffusion simulation result for the diffusion pattern 520 having the shape of FIG. 14. Referring to FIG. 15, it may be confirmed that diffusion occurs evenly. However, compared to the embodiments of FIG. 8 and FIG. 10, it may be confirmed that diffusion occurs in a narrow range.

The embodiments of FIG. 8, FIG. 10, FIG. 12, FIG. 14 and the simulation results of FIG. 9, FIG. 11, FIG. 13, and FIG. 15 are embodiments that simulate the case where the refractive index of the diffusion pattern 520 is lower than the refractive index of the planarization layer 510. However, diffusion may occur in case that the refractive index of the diffusion pattern 520 is higher than the refractive index of the planarization layer 510.

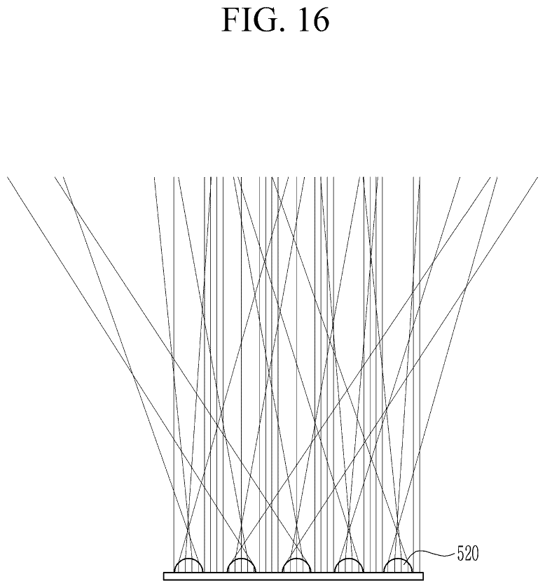

FIG. 16 illustrates a diffusion simulation result in a display device including a diffusion pattern 520 having a shape similar to that of FIG. 8, in which a refractive index of a diffusion pattern 520 is higher than a refractive index of a planarization layer 510. Referring to FIG. 16, it was confirmed that diffusion was performed in case that the refractive index of the diffusion pattern 520 was higher than the refractive index of the planarization layer 510.

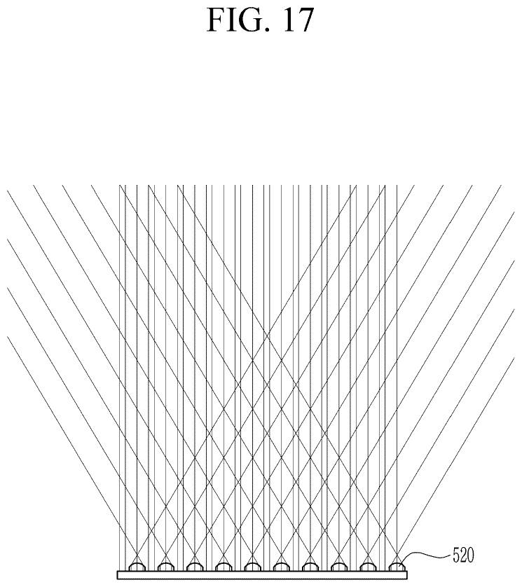

FIG. 17 illustrates a diffusion simulation result in a display device including a diffusion pattern 520 having a shape similar to that of FIG. 10, in which a refractive index of a diffusion pattern 520 is higher than a refractive index of a planarization layer 510. Referring to FIG. 17, it was confirmed that diffusion was performed in case that the refractive index of the diffusion pattern 520 was higher than the refractive index of the planarization layer 510.

Although FIG. 5 illustrates a case where the planar shape of the diffusion pattern 520 is a dot shape, but the planar shape of the diffusion pattern 520 may vary.

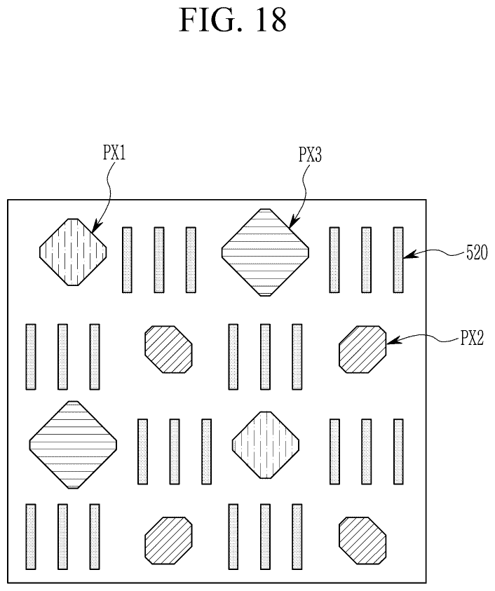

FIG. 18 illustrates the same region as FIG. 5 for another embodiment. Referring to FIG. 18, a display device according to an embodiment is identical or similar to the display device according to the embodiment of FIG. 5 except that the diffusion pattern 520 has a flat bar shape. Descriptions of the same components are omitted for descriptive convenience. Referring to FIG. 18, the diffusion pattern 520 may have a bar shape extending in a direction. For example, a cross-section of the diffusion pattern 520 of FIG. 18 may have a quadrangular shape as shown in FIG. 6, or a circular shape with various radii and heights as shown in FIG. 8, FIG. 10, FIG. 12, and FIG. 14.

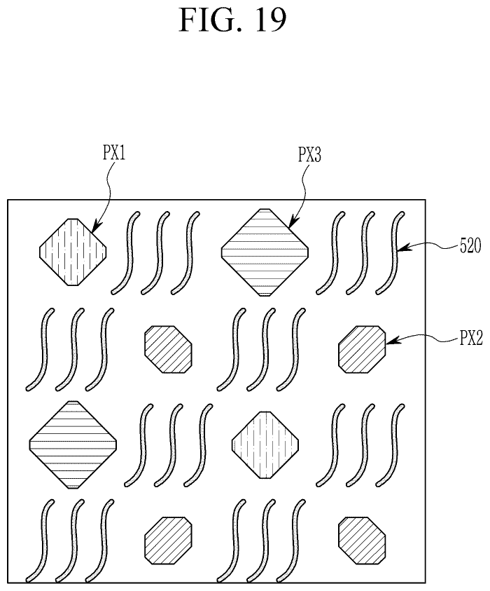

FIG. 19 illustrates the same region as FIG. 5 for another embodiment. Referring to FIG. 19, a display device according to an embodiment is identical or similar to the display device according to the embodiment of FIG. 5 except that the diffusion pattern 520 has a planar wave shape. Descriptions of the same components are omitted for descriptive convenience. For example, a cross-section of the diffusion pattern 520 of FIG. 19 may have a quadrangular shape as shown in FIG. 6, or a circular shape with various radii and heights as shown in FIG. 8, FIG. 10, FIG. 12, and FIG. 14.

In the previous embodiment, the embodiment in which the diffusion pattern 520 is disposed in the space between pixels PX1, PX2, and PX3 in the first area A1 is described, but in another embodiment, the diffusion pattern 520 may be gathered and disposed in some regions of the first area A1.

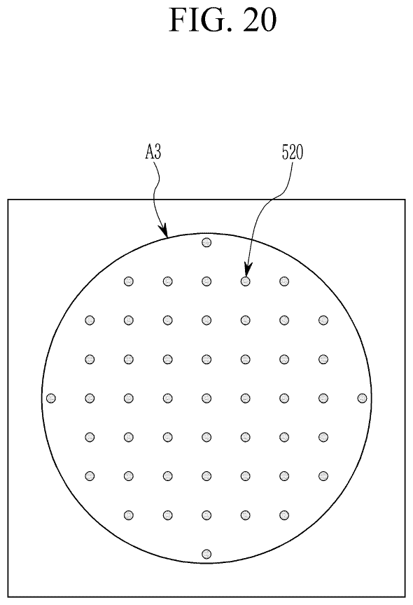

FIG. 20 illustrates the same region as FIG. 5 for another embodiment. Referring to FIG. 20, a refraction area A3 where diffusion patterns 520 are densely disposed within a first area A1. For example, pixels PX1, PX2, and PX3 may not be disposed within the refraction area A3, and the diffusion pattern 520 may be disposed together. The material, shape, and cross-section of the diffusion pattern 520 are the same as those described above, and therefore description of them are omitted for descriptive convenience.

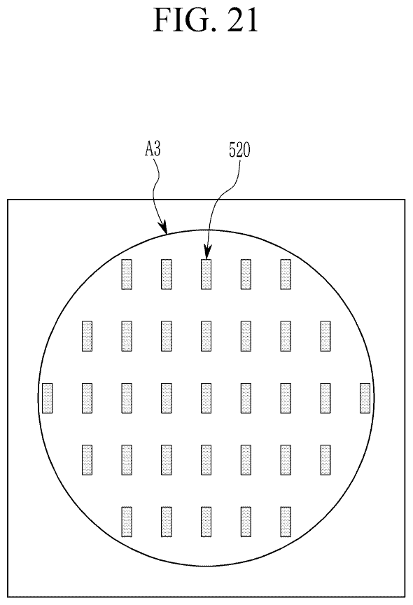

FIG. 21 illustrates the same region as FIG. 18 for another embodiment. Referring to FIG. 21, a refraction area A3 where diffusion patterns 520 are densely disposed within a first area A1. For example, pixels PX1, PX2, and PX3 may not be disposed within the refraction area A3, and the diffusion pattern 520 may be disposed together. The material, shape, and cross-section of the diffusion pattern 520 are the same as those described above, and therefore description of them are omitted for descriptive convenience.

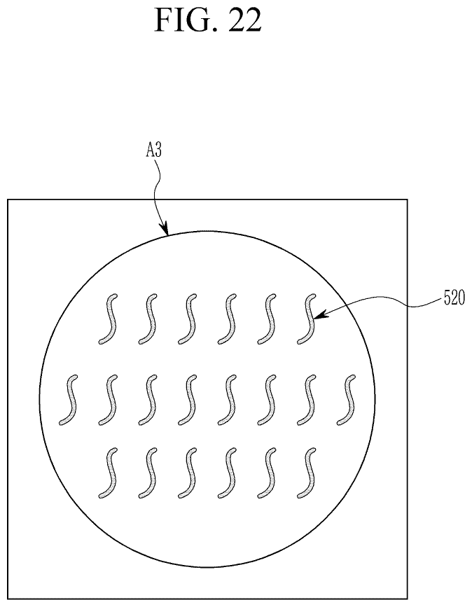

FIG. 22 illustrates the same region as FIG. 19 for another embodiment. Referring to FIG. 22, a refraction area A3 where diffusion patterns 520 are densely disposed within a first area A1. For example, pixels PX1, PX2, and PX3 may not be disposed within the refraction area A3, and the diffusion pattern 520 may be disposed together. The material, shape, and cross-section of the diffusion pattern 520 are the same as those described above, and therefore description of them are omitted for descriptive convenience.

As described above, the display device according to an embodiment may include the second area and the first area in which the sensing module is disposed at a lower area, and the planarization layer and the diffusion pattern having a different refractive index from the planarization layer may be disposed within the first area. Such a diffusion pattern is disposed in the space between pixels and does not overlap the pixels, and may promote diffusion of light from the sensing module, thereby improving the operation of the sensing module.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a display panel including a first area and a second area; and
a sensing module overlapping the first area of the display panel,
wherein the first area of the display panel comprises:
a plurality of pixels;
a diffusion pattern disposed between the plurality of pixels; and
a planarization layer disposed on the diffusion pattern, and
a refractive index of the diffusion pattern and a refractive index of the planarization layer are different from each other.

2. The display device of claim 1, wherein:
the refractive index of the diffusion pattern is smaller than the refractive index of the planarization layer.

3. The display device of claim 1, wherein:
the refractive index of the diffusion pattern is greater than the refractive index of the planarization layer.

4. The display device of claim 1, wherein:
the diffusion pattern does not overlap the plurality of pixels.

5. The display device of claim 1, wherein:
the diffusion pattern is not disposed in the second area.

6. The display device of claim 1, wherein:
a planar area of the diffusion pattern is smaller than a planar area of each of the plurality of pixels.

7. The display device of claim 1, wherein:
a number of diffusion patterns is greater than a number of pixels in a unit area of the first area.

8. The display device of claim 1, wherein:
a planar shape of the diffusion pattern is dot-shaped.

9. The display device of claim 1, wherein:
a planar shape of the diffusion pattern is bar-shaped.

10. The display device of claim 1, wherein:
a planar shape of the diffusion pattern is wave-shaped.

11. The display device of claim 1, wherein:
a cross-section of the diffusion pattern has a circular shape.

12. The display device of claim 11, wherein:
a radius of a bottom surface of the diffusion pattern and a height of the diffusion pattern are substantially equal to each other.

13. The display device of claim 11, wherein:
a height of the diffusion pattern is greater than a radius of a bottom surface of the diffusion pattern.

14. The display device of claim 11, wherein:
a radius of a bottom surface of the diffusion pattern is greater than a height of the diffusion pattern.

15. The display device of claim 1, wherein:
a light emitted from the sensing module is diffused at an interface of the diffusion pattern and the planarization layer.

16. The display device of claim 1, wherein:
the sensing module is an infrared sensing module.

17. A display device comprising:
a display panel including a first area and a second area; and
a sensing module overlapping the first area of the display panel,
wherein the first area of the display panel comprises:
a pixel area where a plurality of pixels are disposed; and
a refraction area where a plurality of diffusion patterns and a planarization layer are disposed,
the plurality of pixels are not disposed in the refraction area, and
a refractive index of at least one of the plurality of diffusion patterns and a refractive index of the planarization layer are different from each other.

18. The display device of claim 17, wherein:
a planar shape of the at least one of the plurality of diffusion patterns is one of a dot shape, a bar shape, and a wave shape.

19. The display device of claim 17, wherein:
a cross-section of the at least one of the diffusion patterns has a circular shape.

20. The display device of claim 17, wherein:
a light emitted from the sensing module is diffused at an interface of the at least one of the plurality of diffusion patterns and the planarization layer.
